(19) United States
(12) Patent Application Publication
(10) Pub. No.: US 2008/0296558 A1
(43) Pub. Date: Dec. 4, 2008

(54) Method of Synthesizing Y-Junction Single-Walled Carbon Nanotubes and Products Formed Thereby

(75) Inventors: Young C. Choi, Miami, FL (US); Wonbong Choi, Miami, FL (US)

Correspondence Address: MARSHALL, GERSTEIN & BORUN LLP, 233 S. WACKER DRIVE, SUITE 6300, SEARS TOWER, CHICAGO, IL, 60606, US

(73) Assignee: THE FLORIDA INTERNATIONAL UNIVERSITY BOARD OF TRUS, Miami, FL (US)

(21) Appl. No.: 11/718,975

(22) PCT Filed: Nov. 14, 2005
(86) PCT No.: PCT/US2005/040995

§ 371 Date: Jul. 24, 2008

Related U.S. Application Data
(60) Provisional application No. 60/627,355, filed on Nov. 12, 2004.

(51) Int. Cl. H01L 29/12; B05D 5/12; B32B 15/04

(52) U.S. Cl. 257/24; 427/122; 428/457; 428/688; 257/E29.069

(57) ABSTRACT

A method has been developed of synthesizing Y-SWNTs with controlled density, position, and growth direction. The process includes patterning a substrate with a solvent solution of catalyst metal ions, dopant metal ions and metal oxide ions, having in a molar ratio of catalyst to dopant in the range of 0.1 to 0.5 moles of catalyst metal per mole of dopant metal, prior to heating to 600-1200° C. with a flow of hydrocarbon gas. A Y-SWNT can be used as a building component of nanoscale two- and three-terminal electronic devices, such as interconnects, diodes, and transistors. This development has a profound impact on nanoscale semiconductor industry, since it is certain that the market share of nanoscale devices using Y-SWNTs will be increased to a great extent.

### CROSS-REFERENCE TO RELATED APPLICATION

The present application claims the benefit of provisional application Ser. No. 60/627,355 filed Nov. 12, 2004. The entire text of the priority application is incorporated herein by reference in its entirety.

### FIELD

The miniaturization of electronic devices into nanometer scale is an indispensable stage for next-generation semiconductor technology. The first step in accomplishing this goal is to synthesize nano-materials which can be used as building components for nano-devices. Among a variety of nanoscale materials, Y-junction single-walled carbon nanotubes (Y-SWNTs) have attracted much attention due to their potential to be used as future nano electronic devices, such as nano-scale transistors.

### BACKGROUND

Since the energy band gap of a semiconducting SWNT is dependent upon its diameter and chirality, a Y-SWNT having variations in tube diameter and/or chirality between branch and stem will make it possible to produce three-terminal nanoscale devices, where the third terminal can be used for controlling switching, power gain, or other properties associated with semi-conductor devices, such as ambipolar field-effect transistors. The literature contains theoretical predictions concerning the electronic transport characteristics of Y-SWNTs: Andriotis, et al., Physical Review Letters, “Rectification properties of carbon nanotube ‘Y-junctions’”, 87(6):066802 (2001). Although methods for synthesizing Y-junction multiwalled carbon nanotubes (Y-MWNTs) have been developed: Gothard, et al., Nano Letters, “Controlled Growth of Y-Junction Nanotubes Using Ti-Doped Vapor Catalyst”, 4(2):213-217 (2004), at present the literature does not disclose a method of producing Y-SWNTs in a controlled manner. Hence, methods of synthesizing Y-SWNTs are very important for next-generation nanoscale semiconducting device applications.

### SUMMARY

Disclosed are methods of synthesizing Y-junction single-wall carbon nanotubes that can be manufactured either as metallic or semi-conducting based upon the materials used in the synthesis. The synthesis method disclosed herein is reproducible for producing Y-SWNTs using chemical vapor deposition (CVD) techniques which may be either thermal-CVD or plasma-CVD method. The Y-SWNTs are grown on a substrate, such as silicon, quartz, or metal plates. In a preferred embodiment for forming a field effect transistor, the substrate is first coated with an insulating coating, or has a natural oxide surface, such as SiO₂, by a spin coating technique and then the SiO₂ coating is air dried at room temperature. If the substrate is aluminum oxide or other suitable insulator that is stable at reaction temperature, the SiO₂ layer would not be needed. The coated substrate is then sputtered with or otherwise has nanoparticles of solvent solution, containing a mixture of catalyst metal ions, dopant metal ions and metal oxide nanoparticles, deposited thereon. Another important feature of the methods described herein for forming single-wall Y-branched carbon nanotubes is to include the metal oxide catalyst support material in the catalyst/dopant solution, preferably aluminum oxide and/or magnesium oxide, as nanoparticles. Any metal oxide that is stable at reaction temperature is suitable. The metal oxide is important to maintain the catalyst and dopant metals in contact, and effective, with the leading edge of the forming single-wall nanotubes. Preferred solvents for the catalyst/dopant and metal oxide nanoparticles are methanol and/or ethanol. The catalyst concentration should be in the range of about 1 mg to 500 mg per 100 ml. of solvent; the dopant and metal oxide concentrations should be about 1 mg to 100 mg per 100 ml. of solvent. After the particles are dried, the substrate is loaded into a CVD reactor followed by heating to 600 to 1200° C., preferably 700 to 1000° C. under non-oxidizing conditions, e.g., under a blanket of argon gas. After the temperature in the CVD reactor reaches equilibrium, a hydrocarbon gas, e.g., methane, is injected into the CVD reactor to begin the synthesis of single-walled Y-branched nanotubes.

In order to provide Y-branching on the synthesized single-wall nanotube stems, it is necessary to nucleate a single-walled nanotube on the single-walled nanotube stem. The Y-branched SWNT is nucleated on the stem SWNT by attaching a catalyst particle to the side wall of the stem. The catalyst can be any carbide-forming metal atom such as iron, cobalt, nickel, or the like, preferably iron. In accordance with the process described herein, Y-branched SWNTs are formed by providing a solution of catalyst and dopant in a suitable solvent, such as ethanol, and including a metal oxide catalyst support material, in nanoparticles, in the solution. The dopant metal should have a carbide-forming Gibbs free energy less than that of the catalyst metal, preferably titanium, zircomium or molybdenum, to provide doped iron carbide particles with a stronger driving force for attachment to a side surface of the growing single-wall carbon nanotube stems. The dopant is included with the catalyst in solution, e.g., iron, at a molar ratio of catalyst metal to dopant metal, e.g., Fe/Mo, Fe/Zr, Fe/Ti within the range of 1% to 50%, preferably 5% to 30%. If the catalyst metal is iron, as preferred, the dopant metal is Ti, Zr, Hf, V, Nb, Ta, Cr, Mo, and/or W.

### BRIEF DESCRIPTION OF THE DRAWINGS

FIG. 1a shows a proposed structure of a Y-SWNT wherein S.C. is an abbreviation for semiconductor.

FIG. 1b and 7 show a schematic of a proposed nanoscale transistor using a Y-SWNT having two semiconducting single-walled nanotubes and a third metallic branch formed by a carbon nanotube.

FIGS. 2a, 2b, and 2c show a proposed growth mechanism of Y-branched single walled nanotubes;

FIG. 3a and FIG. 3b show SEM and TEM images of Y-branched single-walled nanotubes;

FIG. 4 is a schematic flow diagram showing the apparatus and method for growing Y-branched single-wall nanotubes described herein;

FIG. 5 is a graph showing the Raman spector of Y-SWNTs produced by the method described herein;

FIG. 6 is an SEM image of a field-effect transistor (FET) made from a Y-SWNT made by the method described herein;

FIG. 7 is a schematic diagram of the FET shown in FIG. 6 showing the FET circuit;

FIG. 8 is a graph of current versus voltage characteristics of nanotubes formed from different materials;

FIG. 9 is graph of drain current versus drain voltage for a Y-SWNT device under a positive and negative gate voltage;

FIG. 10 is a graph of drain current versus gate voltage for different drain voltages applied to the Y-SWNT of FIG. 9;

FIG. 11A, 11B and 11C illustrate a physical process for forming a Y-SWNT three terminal device; and

FIG. 12 shows an electrode embodiment for controlling the growth direction of Y-SWNTs.

### DETAILED DESCRIPTION

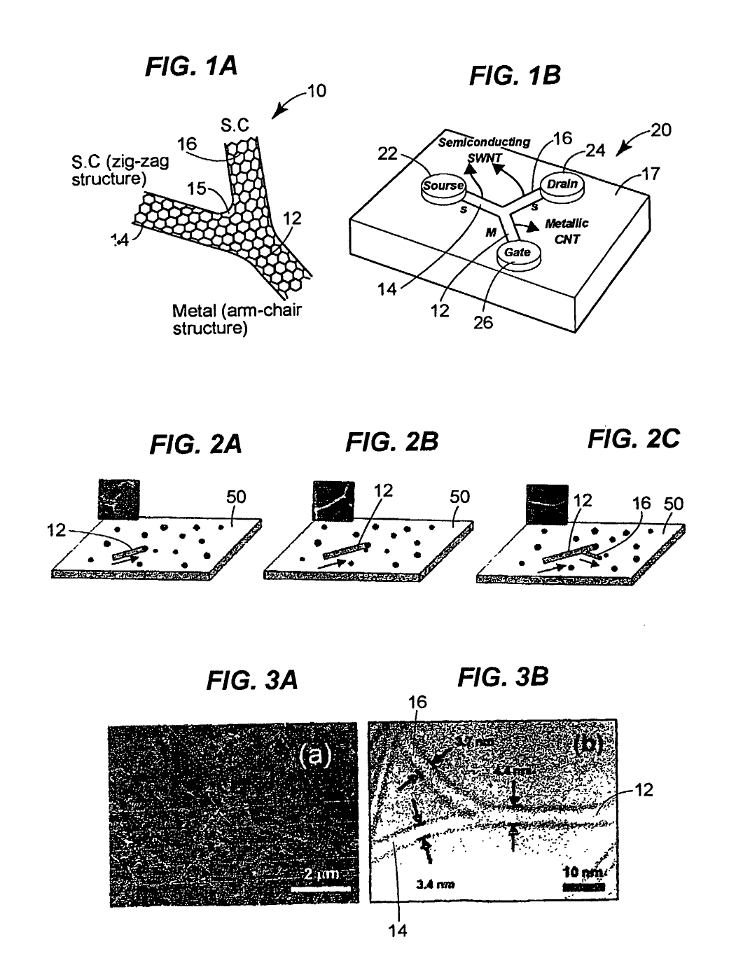

FIG. 1(a) shows a proposed structure 10 of one example of a Y-SWNT which can be used in the fabrication of three-terminal nanoscale devices. The stem 12 is a single-wall carbon nanotube having an arm-chair conducting structure of hexagonal carbon atoms that form the stem 12, and the Y-branches 14 and 16 are semiconductor single-wall carbon nanotubes having a zig-zag structure. Upon formation, at the juncture of the Y-branches, a portion of the metal oxide 15 contained in the catalyst/dopant/metal oxide solution initially applied to the substrate 17 (FIG. 1b), adheres to both branches 14 and 16 where the branches 14 and 16 meet. This oxide portion 15 can be removed, if desired. FIG. 1(b) shows a schematic diagram of a proposed nanoscale transistor 20 formed from the Y-branched nanotube of FIG. 1a. Semiconducting SWNTs are connected, respectively, to source electrode 22 and drain electrode 24, and the metallic (conductor) SWNT 12 is connected to a gate electrode 26. A Y-SWNT could also be used in the manufacture of nanoscale diodes and interconnects by controlling its chirality.

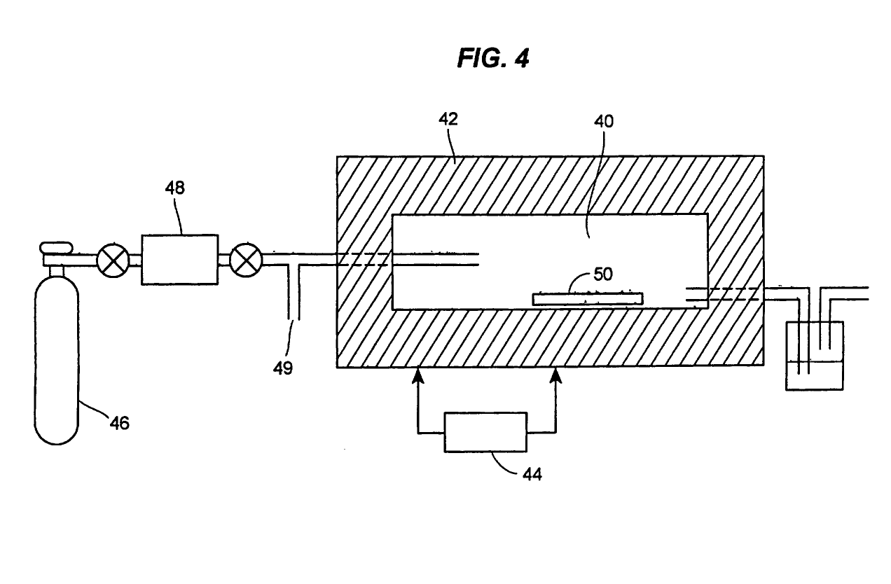

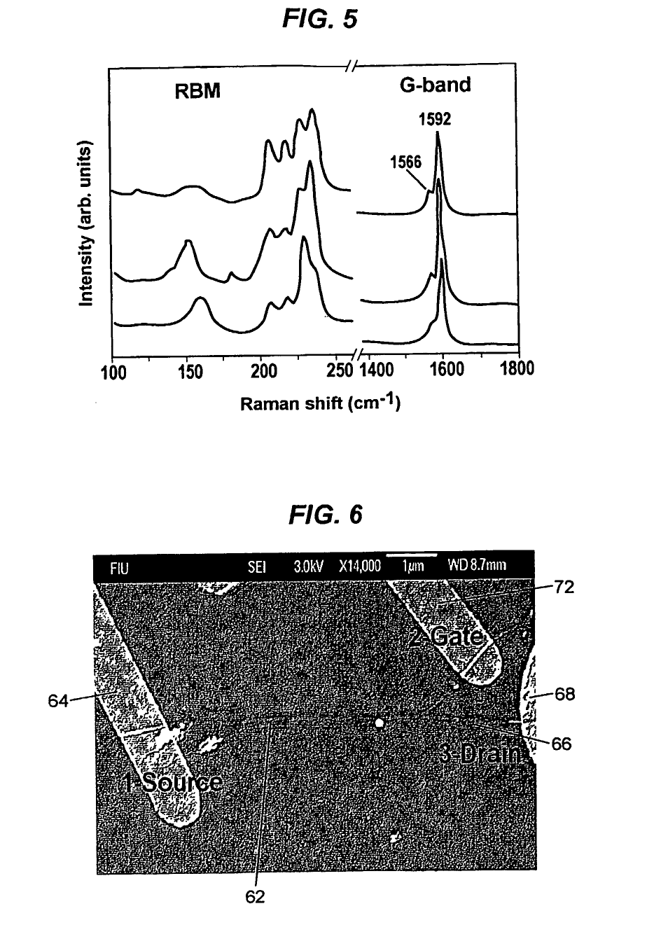

The scanning electron microscopy (SEM) image (FIG. 3a) shows the Y-branching of carbon nanotubes. Most of synthesized nanotubes have branches forming Y-shaped junctions. The particles placed beneath the Y-junctions are Mo-doped Fe catalyst particles supported by aluminum oxide. Before the synthesis of the Y-junction SWNT, the spin coating of catalyst solution was carried out with a spinning rate of 3500 revolutions per minute (rpm). In order to investigate the morphology of catalyst particles, the spin-coated substrate was heated to 900° C. in an Ar atmosphere, and then the substrate was cooled to room temperature without introducing CH₄ gas for nanotube growth. The morphology of catalyst particles was similar to that of FIG. 3a. Energy dispersive X-ray spectroscopy (EDS) analysis indicated that the particles are composed of mainly Fe and Al with a small amount of Mo. It was found that the density of catalyst particles decreases with increasing spin-coating speed. Note that the density of the Y-junction SWNT is varied with that of catalyst particles from which the nanotubes nucleate and grow. By varying the spinning speed from 1000 rpm to 7000 rpm, the number of Y-branching SWNTs is decreased from approximately 2.9×10⁸ cm⁻² to 5.7×10⁷ cm⁻². It was found from FIG. 3b and 3c that a Y-junction is formed by a new nanotube nucleated on the wall of another nanotube that was previously nucleated and being grown (FIG. 3b); that the diameters of branched nanotubes are usually smaller than those of the stems (FIG. 3b); and that more Y-junctions can be formed on other positions of the stems and/or on the nanotube branches, forming multiple Y-junctions.

The present invention is directed to a method for forming branched single-walled nanotubes and, in a preferred embodiment, the branched nanotubes are used to form three-terminal nanoscale devices, such as ambipolar field-effect transistors, according to the disclosed method. The disclosed method is a chemical-vapor deposition (CVD) method in which a carbide-forming dopant and a metal catalyst are solubilized in a suitable solvent, such as, deionized water, methanol and/or ethanol and the solution is mixed with metal oxide particles. The solution is deposited as nanoparticles (less than 1 mm. in diameter), for example, by photolithography, onto a substrate coated with, or having, an insulating upper layer, e.g., SIO₂, or Al₂O₃. A hydrocarbon gas, such as methane, is fed to the CVD reactor 40 (FIG. 4) at high temperature, e.g., 600-1200° C., preferably 700-1000° C. to form Y-branched SWNTs. The presence of a carbide-forming dopant metal and a metal oxide, such as aluminum oxide and/or magnesium oxide, in the catalyst solution leads to the formation of SWNT stems and subsequent formation of nucleation sites or Y-branching loci along the walls of the growing nanotube stems. Nanotube Y-branches develop and grow from the nucleation sites but would not form on SWNTs without the catalyst-stabilizing effect of the metal oxide. Each branch can then continue to grow independently as long as a carbon source remains available at the high temperature reaction conditions. The disclosed process can be carried out in any CVD carbon nanotube formation process.

FIG. 4 illustrates one embodiment of the CVD reactor 40 that can be used to grow highly aligned and high purity Y-branched nanotubes. Reactor 40 can be disposed within a furnace 42 that can be controlled such as by temperature controller 44 to provide a controlled temperature within the reactor 40.

An inert gas flow can be supplied to the reactor 40, via tank 46, to provide a carrier flow for materials into the reactor 40. In the preferred embodiment, the inert carrier gas is argon. Optionally, the carrier gas can include additional materials, such as hydrogen. Flow controller 48 can be used to control the flow of inert gas to the reactor 40.

The reactor 40 also includes an inlet port 49 for the flow of one or more hydrocarbon gases, such as methane, acetylene or ethylene, into the reactor 40. A substrate, such as an insulator-coated, e.g., SiO₂-coated substrate 50, and carrying doped and metal oxide-containing catalyst solution, at precise locations, applied, e.g., by photolithography, is delivered directly into the reactor 40, prior to heating the reactor 40 to reaction conditions, in order to form one or more field effect transistors on a single substrate 50. For example, four Y-branched single-wall nanotubes can be grown on substrate 50 (4″ by 4″) to produce four FETs.

The carbon source fed to the reactor 40 is generally a hydrocarbon that can, upon decomposition in the reactor 40, provide the elemental carbon for formation of the nanotubes. For example, in one embodiment, the carbon-containing precursor material can be xylene, ethylene, acetylene, methane, or benzene. The carbon source need not be limited to a hydrocarbon, however, and can be any suitable carbon-containing material that can decompose in the furnace to provide the elemental carbon necessary for growth of the developing nanotubes. The preferred carbon source for forming Y-branched single-walled nanotubes is methane, acetylene and/or ethylene.

According to one particular embodiment of the present invention, the carbon source can be derived, at least partly, from an organic solvent that can also serve as a solvent for one or more of the catalyst, and/or carbide-forming dopant materials, e.g., pure ethanol. According to this embodiment, a catalyst and dopant are dissolved in the organic solvent and the liquid solution containing both, as well as metal oxide nanoparticles, are applied to an insulator-coated, e.g., SiO₂-coated silicon, quartz or glass substrate.

The materials fed to the reactor 40 may also include a component that contains a portion of the carbide-forming catalyst, metal oxide and dopant necessary for nucleation of the single-walled nanotubes and nucleation of the nanotube branches, in addition to the catalyst/dopant solution and metal oxide initially patterned, e.g., by photolithography, on the insulator-coated substrate 50. The catalyst can be any suitable metal that forms a metal carbide to initiate nanotube formation in the reactor 40. For example, metallic catalysts such as iron, cobalt, nickel, and the like can be utilized in the reactor 40 to initiate formation of the nanotubes and the Y-branches. In general, the catalyst can be a carbide-forming metal atom, preferably iron. In one particular embodiment, the catalyst-containing material soluble in the solvent, e.g., methanol, can be a metallocene, for instance ferrocene, cobaltocene, nickelocene, and the like.

In accordance with an important feature of the Y-branched SWNT process and articles described herein, the substrate is first patterned with a solution of catalyst and dopant admixed with metal oxide nanoparticles, e.g., by photolithography, in defined areas prior to heating the CVD reactor 40 to the high temperature reaction conditions. Also, to achieve the full advantage of the process described herein, the catalyst/dopant molar ratio, in solution, should be in the range of 0.01 to 0.5 moles of catalyst metal-containing molecule for every mole of dopant metal-containing molecule. The combination of the catalyst metal, carbide-forming dopant metal and the metal oxide catalyzes nucleation of Y-branches of the nanotubes at the side surfaces of the single-wall nanotube stems formed within the reactor in a earlier stage of the process. Without the metal oxide catalyst support particles, the catalyst and dopant metals would not be available to catalyze Y-branch formation.

The carbide-forming dopant, catalyst and metal oxide particles can be supplied in the catalyst/dopant/metal oxide solution in any suitable form, i.e., in a form that can provide the elemental dopant metal and catalyst metal in solution mixed with and metal oxide particles. For example, when molybdenum is the dopant metal, the Mo dopant can be bislacetylacetonado)-dioxo-molybdenum.

The conditions in the CVD reactor 40 during the disclosed process can generally be equivalent to those of other CVD nanotube formation processes as are known in the art. For example, reactor 40 can be heated to a temperature between about 600° C. and about 1200° C., preferably about 700° C. to about 1000° C., more preferably about 850° C. to about 950° C., under non-oxidizing conditions, e.g., under a blanket of argon gas. Within the reactor 40, single-walled stems and single walled Y-branches on the stems of the previously formed nanotubes grow spontaneously in highly ordered arrays on the substrate 50, spin-coated with a SiO₂ layer, for instance a quartz substrate 50, or any other suitable substrate material as is generally known in the art.

According to the process described herein, when the catalyst/dopant solution, mixed with metal oxide nanoparticles is deposited onto the surface of the substrate 60 in defined areas, and the CVD reaction is heated to reaction temperature, Y-branches spontaneously form on the developing nanotubes.

### Synthesis Method

The present invention is directed to methods for preparing a catalyst and dopant solution and metal oxide particles on substrates, and to methods of using the catalyst/dopant/metal oxide solutions to grow Y-branched, single-wall carbon nanotubes. An exemplary catalyst/dopant/metal oxide deposition pattern includes a uniform dispersion of catalyst/dopant/metal oxide nanoparticles solution deposited by photolithography on the surfaces of a SiO₂-coated substrate 50. In these methods, the insulator-coated substrate, including the catalyst/dopant/metal oxide combination patterned on the surface of the insulator coating is placed into the CVD reactor 40 and heated to a high temperature, preferably 800-1000° C. A carbon-containing gas, e.g., methane, is then passed through the reactor for a period of time. Nanotube growth is catalyzed from the carbon-containing gas by the previously deposited solution of the catalyst, dopant and metal oxide nanoparticles.

An embodiment of a reactor for implementing methods of the present invention includes the heating component or furnace 42 and the tube reactor 40 (FIG. 4). The tube reactor 40 is made of material, such as quartz, that can withstand a high temperature ranging from 600° C. to 1200° C., preferably 700 to 1000° C., and more preferably from 850 to 950° C. The diameter of the tube reactor will depend on the particular application. Exemplary carbon-containing gases include hydrocarbon gases such as aliphatic hydrocarbons, both saturated and unsaturated, including methane, ethane, propane, butane, hexane, ethanol, acetylene, ethylene, and propylene. Other exemplary carbon-containing gases include carbon monoxide, oxygenated hydrocarbons such as acetone and methanol, aromatic hydrocarbons such as toluene, benzene and naphthalene, and mixtures of the above. Methods described herein yield single-walled Y-branched nanotubes. Preferred carbon-containing gases for promoting the growth of single-walled Y-branched carbon nanotubes include methane, ethylene, acetylene and carbon monoxide. Since methane is the most stable of these hydrocarbons at high temperatures against self-decomposition, catalytic decomposition of methane by transition-metal catalyst/dopant/metal oxide mixed nanoparticles is the preferred process in the Y-branched SWNT growth process described herein. It will be understood that the temperature during carbon nanotube growth does not need to be held constant and can be ramped or stepped either up or down during the growth process.

Deposition of the catalyst and dopant solution, mixed with the metal oxide catalyst support particles, by a photolithography process, in one embodiment, can employ multiple photolithographic targets. In one embodiment a plurality of photolithographic targets are used, one target comprising a first catalyst/dopant/metal oxide combination in solution, and a second target comprising a second catalyst/dopant/metal oxide combination in solution.

More generally, the deposition of the catalyst, dopant solution and metal oxide particles onto the insulator-coated substrate can be achieved in any number of conventional techniques such as photolithography, sputtering, evaporation, electro-deposition, laser ablation, and arc evaporation.

A reproducible method of synthesizing Y-SWNTs using chemical vapor deposition (CVD) techniques also may include thermal- and/or plasma-CVD. The substrate on which the catalyst, dopant solution and metal oxide particles are prepared is loaded in a CVD reactor, followed by heating to 600-1200° C. under non-oxidizing conditions—e.g., under a blanket of argon gas. After the temperature reaches equilibrium, a hydrocarbon gas, e.g., methane, is injected into the CVD apparatus to synthesize Y-SWNTs, followed by cooling.

In order to form Y-branching, a branched SWNT should nucleate on a stem SWNT. A method for causing such nucleation is by attaching the doped catalyst particles to the sidewall of stem SWNTs. If iron is used as the catalyst, Fe particles should first be reacted with carbon to form iron (Fe) carbide for proper attachment of Fe particles onto the nanotube wall. However, the 3Fe+C=Fe₃C reaction is unfavorable at nanotube growth temperatures (e.g., 700-800° C.) since the Gibbs free energy (ΔG_{f}) for the reaction is positive. Although Gibbs free energy of the reaction at 900-1,000° C. is negative, the absolute value is small (ΔG_{1,173}K=−0.375 kcal/mol), which means less probability of carbide formation. Hence, the key process for Y-junction formation is to dope carbide forming elements to Fe particles and make the catalyst/dopant metals available for Y-branching by including a catalyst/dopant metal oxide stabilizer, e.g., aluminum oxide and/or magnesium oxide. The metal oxide stabilizer must be a metal oxide that itself, is stable at the CVD reactor temperature. Fe particles doped with a carbide-forming dopant, such as Ti, Hf; Mo or the like, forms the dopant metal carbide that is attached by the formation of the dopant metal carbide on the side wall of the nanotube stem, and then a new SWNT nucleates and grows, forming Y-junctions. Forming the dopant metal carbide is much easier than that of forming Fe₃C when a carbon nanotube meets a catalyst particle. Doped Fe particles, the afore, have a stronger driving force for being attached to SWNTs than pure Fe particles (FIG. 2c). The metal oxide particles stabilizes and supports the catalyst/dopant solution, thereby making the catalyst/dopant available for Y-branch formation in SWNTs.

### EXAMPLE 1

In order to prepare Mo-doped Fe catalyst particles on the substrate, iron (III) nitrate monahydrate, aluminum oxide nanoparticles, and bis(acetylacetonato)-dioxomolybdenum (VI) were dissolved in alcohol. The resultant solution was spread on an SiO₂-coated Si substrate by conventional spin coating techniques, and then dried in air at room temperature. Exemplary substrates that can be used for synthesizing Y-SWNTs include Si, quartz, metal plates, and the like. Spin-coating involves rotating the substrate at high speed while depositing the solution onto the substrate.

SEM shows that most of the synthesized SWNTs have branches, forming Y-junctions (FIG. 3a). Transmission electron microscopy (TEM) images confirmed that a Y-SWNT consists of three isolated SWNTs with diameters ranging from 1-5 nm, as shown in FIG. 3b.

Radial breathing mode (RBM) and two components of the G-band peak in the Raman spectra also confirmed that the Y-SWNTs which were synthesized are composed of SWNTs (FIG. 4). Furthermore, the analysis of the RBM peaks indicates that samples prepared according to the above procedure have both semiconducting and metallic SWNTs. Use of a laser with an excitation wavelength of 785 mm reveals RBM peaks located at 140 cm⁻¹ to 175 cm⁻¹ which originate from metallic SWNTs, and the presence of semiconducting SWNTs as shown by the peaks at around 120 cm⁻¹ and at 210 cm⁻¹ to 250 cm⁻¹. These observations are indicative of formation of Y-branching wherein at least one of the branches has different electrical properties.

### EXAMPLE 2

Y-SWNTs are grown successfully by a thermal chemical vapor deposition (CVD) method with Fe/Mo catalyst/dopant and aluminum oxide nanoparticles. The Fe/Mo catalyst/dopant solution is prepared by dissolving Iron (III) nitrate nonahydrate, bis (acetylacetonato)-dioxomolybdenum (VI), and aluminum oxide nanoparticles into methanol following by 30 minutes sonication to form a homogeneous suspension. One drop of the catalyst solution is dropped onto a SiO₂/Si substrate which is then loaded in a quartz tube CVD-reactor. Then the temperature of quartz reactor is ramped up to 600-1000° C. in an Ar atmosphere (1000 sccm). After the temperature is stabilized, Ar gas flow is replaced by CH₄ and H₂ (500 sccm for each gas) for the synthesis of Y-branched SWNTs. Finally the quartz tube reactor is cooled to room temperature in a gas flow of 1000 sccm of Ar.

FIG. 6 illustrates an electron microscopy image of a Y-junction single-walled carbon nanotube (Y-SWNT) 60 embodiment of the invention. As illustrated in FIG. 6, the Y-SWNT is formed from three nanotube branches 62, 66, 70. A stem 62 is electrically coupled to a first metal deposition 64 forming a first terminal. A first arm 66 is electrically coupled to a second metal deposition 68 forming a second terminal. A third arm 70 is electrically coupled to a third metal deposition 72 forming a third terminal. The Y-SWNT structure 60 can then be used as a three terminal device that exhibits rectifying and transisting properties (discussed further below).

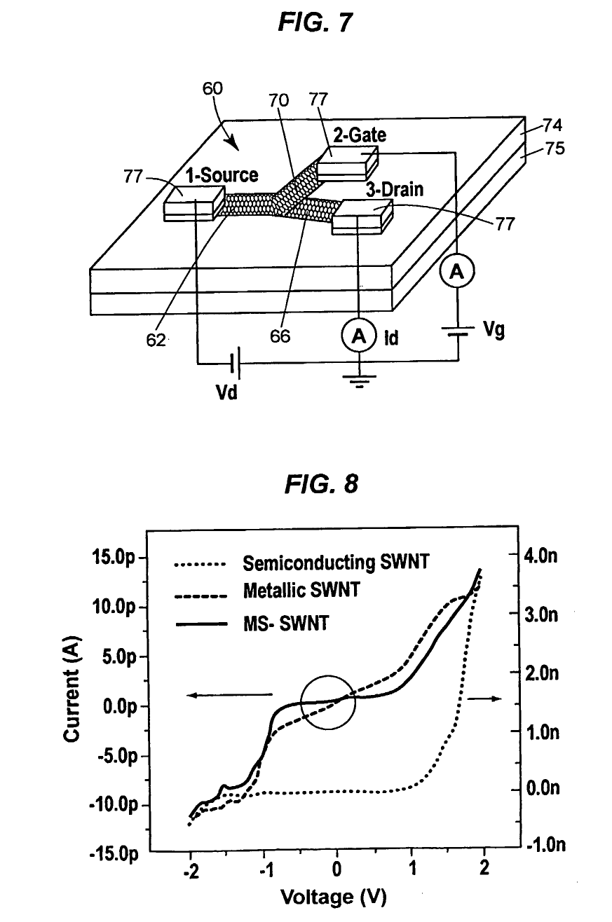

FIG. 7 illustrates a perspective model of the Y-SWNT 70 device of FIG. 6. A SiO₂ layer 74 is formed on top of a Si substrate layer 75. The Y-SWNT 70 is disposed on the SiO₂ layer 74. Metal deposits 77 near the terminals of the Y-SWNT structure are electrically coupled to the nanotubes, thereby forming electrodes. The metal deposits 77 can be any suitable conducting material that can bond appropriately to the particular base layer, e.g., nickel, platinum, gold, titanium, etc. When appropriate voltages Vd and Vg are applied to the electrodes, the nanotube structure exhibits current-voltage characteristics of a rectifying device. Specifically, the stem of the Y-SWNT 62 can be biased against a first arm 66 at a first voltage Vd, and when a second voltage Vg is applied to the second arm 70, a source current Id will flow between the first arm and stem. Thus, the stem 62 may act as a source, the first arm 66 may act as a drain, and the second arm 70 may act as a gate. In one embodiment, the stem of the Y-SWNT is longer than the other two arms. In another embodiment the length of the two arms may be substantially equal.

As discussed above in FIG. 1b, nanotubes can be constructed using either metallic or semiconducting material. The Y-SWNT can be formed as a heterojunction of metallic and semiconducting tubes. For example, in one embodiment, the stem and a first arm may be constructed of semiconducting material while the second arm may be constructed of metallic material. The stem and first arm may correspond to a source and drain terminal, respectively, of a three terminal device, while the second arm may correspond to a gate terminal. In one embodiment, the semiconducting material of the stem and first arm may be constructed to be p-type, however, the semiconducting material may also be made n-type.

The current-voltage (I-V) characteristics of nanotubes using different material is illustrated in FIG. 8. The I-V characteristic curves of FIG. 8 may also be representative of individual tubes of the Y-SWNT of FIGS. 6-7, effectively demonstrating two terminal device operation. As shown in FIG. 8, the semiconducting material nanotube shows a rectifying characteristic curve having little reverse bias leakage current with a negative breakdown voltage outside the range of the graph. A positive voltage greater than 1 volts prompts a exponential current spike thus setting the semiconducting nanotube turn-on voltage at about +1 volt. The semiconducting nanotube exhibits the I-V characteristics of a common diode.

The metallic nanotube, on the other hand, displays a negative breakdown voltage of about −1 volts and a positive turn-on voltage of about +1 volts. The (metallic/MS) nanotube displays an almost linear I-V characteristic for the same gap period (between −1 to +1 volts) but shows a turn-on voltage at about +1 volts, e.g., the current increases slightly more rapidly past +1 volts. A metallic-semiconducting (MS) nanotube, created using a metallic tube portion and semiconducting tube portion coupled at a heterojunction, demonstrates little to no leakage current for a voltage gap between −1 and +1 volts. It has a sharper turn-on voltage at +1 volts and a sharper negative breakdown voltage at −1 volts than the metallic nanotube. The rectification ratio (defined as the ratio of forward to reverse current) for the MS nanotube is about 300-500 at 2V. Therefore, the MS nanotube may provide bi-directional rectifying characteristics.

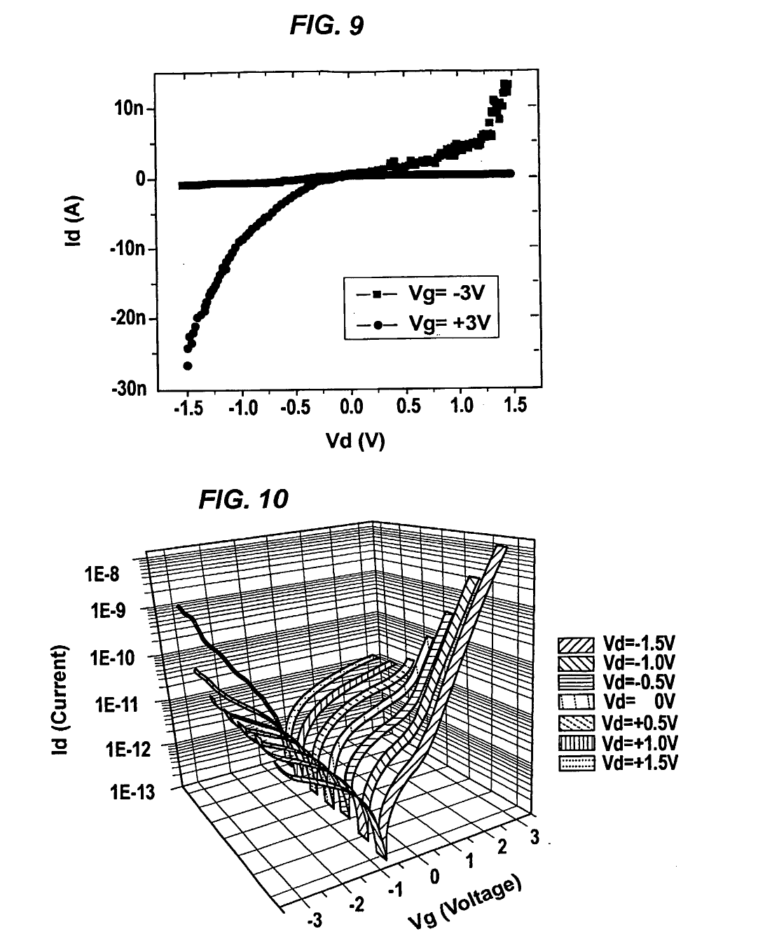

FIG. 9 illustrates the I-V characteristics of the Y-SWNT structure under two different gate voltages. Specifically, the source-drain current is shown against the source-drain voltage for a positive and a negative gate voltage, one at −3V and a second at +3V. As illustrated in FIG. 9, a positive gate voltage allows a negative current to flow through the source-drain terminals, and a negative gate voltage allows current to flow in the opposite positive direction. Therefore, the Y-SWNT device may be used as a bi-directional rectifying device. The device exhibits the characteristics of an ambipolar transistor. The Y-SWNT device is capable of providing about a 700 mV/decade swing and Ion/off ratio of 105 with a low off-state current in the 10-13 range. The charge mobility in one embodiment is about 6.3 cm²/vs for electrons and 0.83 cm²/Vs for holes at room temperature. While magnitudes of the charge mobilities may not be as high as conventional devices, e.g., MOSFETs, the charge mobilities are higher than those of organic ambipolar transistors.

FIG. 10 illustrates the drain current versus gate voltage for different drain voltages applied to the Y-SWNT device. At positive gate voltages, the electron carrier currents (n-type) increase, but split at negative drain voltage, where hole currents are small and overlap with the electron currents. At negative gate voltage, hole current increases (p-type) and split at positive drain voltages. The metallic gate arm may form a Schottky barrier with the semiconducting branches at the heterojunction. A voltage applied on the gate terminal can modulate the Schottky barrier at the junction, and effect the carrier concentration (both electrons and holes) and corresponding depletion regions at the junction. Thus, the voltage at the gate can effect current flow between the source and drain. FIG. 10 also shows that the I-V curves are substantially stable for different drain voltages, where the drain current is more dependent upon the polarity of the gate voltage than the magnitude of the drain voltage.

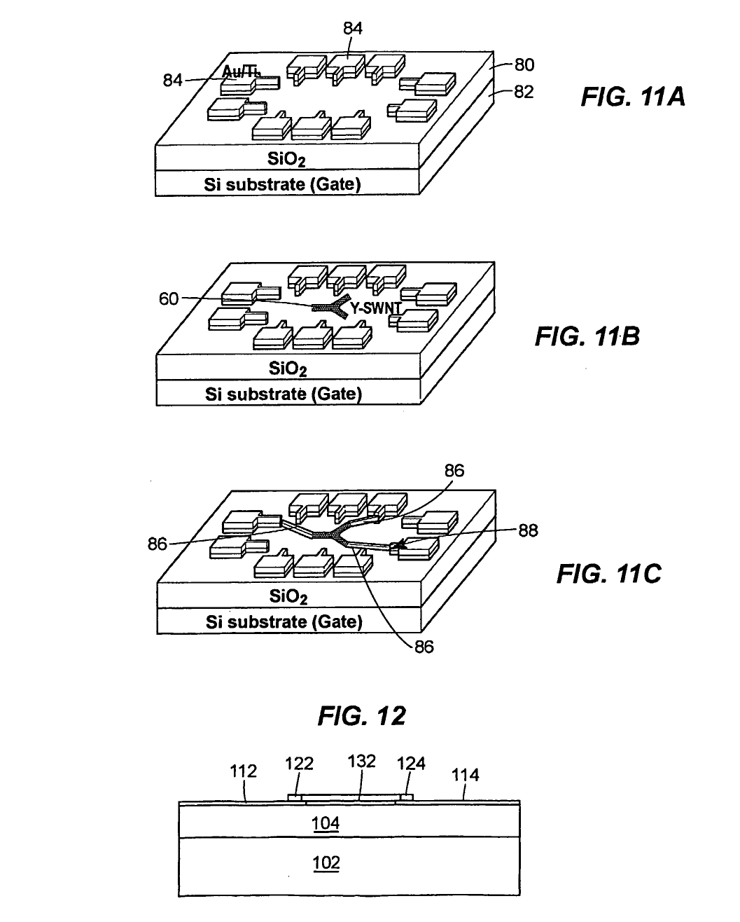

FIGS. 11A-11C illustrate a process in which the Y-SWNT device may be formed. FIG. 11A illustrates a first process block in which a SiO₂ layer 80 may be formed on top of a Si substrate layer 82. A SiO₂ layer of about 500 nm can be used. A set of metal electrodes 84 may be deposited in a rectangular pattern on the SiO₂ layer 80. The pattern may be formed using photolithography. A sputtering process may be used to deposit the metal followed by a lift-off process. As suggested by FIG. 11A, the metal electrodes 84 may be gold and/or titanium.

FIG. 11B illustrates a second process block in which the Y-SWNT 60 may be formed on the SiO₂ layer 80 and within the rectangular perimeter of the metal electrodes 84 using a dispersion process. The position of the Y-SWNT can be confirmed using a Field Emission Scanning Electron Microscope. FIG. 11C illustrates a third process block for developing the connections between the Y-SWNT and terminating electrodes. An etching layer, e.g., poly-methylmethaacrylate (PMMA) may be applied over the SiO₂ layer surrounding the Y-SWNT and an e-beam lithography process performed to form a pattern for electrical connections 86 between the Y-SWNT 60 and the surrounding electrodes. After pattern formation, metal connections 88 are deposited using a sputtering process. The metal connections 88 may be made out of a combination of metals such as titanium and gold. A ratio of 20 nm of Ti to 80 nm Au can be used.

### Method Of Controlling Density And Growth Direction And Position

Procedures for controlling the density of Y-SWNTs have also been developed. By increasing the spin coating speed of the substrate during application of the catalyst/dopant/metal oxide solution from 1,000 revolution per minute (rpm) to 6,000 rpm, the density of Y-SWNTs was decreased from approximately 2.9×10⁸ cm⁻² to 5.7×10⁷ per cm².

The growth direction of Y-SWNTs can also be controlled while the SWNT is being formed by applying an electric field, as described in U.S. Pat. No. 6,837,928 B1, hereby incorporated by reference. FIG. 12 shows an arrangement for electric field alignment of Y-branched SWNT carbon nanotubes. The arrangement includes a substrate 102, e.g., Si (gate), with an insulating layer of SiO₂ 104 thereon. Electrodes 112 and 114 are disposed on the SiO₂ insulating layer 104, and are made using conductive material, such as molybdenum or other metal. Catalyst/dopant/metal oxide solution portions 122 and 124 are formed on the electrodes 112 and 114, respectively, with the electrodes being adapted for coupling to a power source for applying an electric field between the catalyst islands. A nanotube 132 is then subsequently grown between the catalyst/dopant solution portions 122 and 124, using the electric field applied via the electrodes 112 and 114. The electric field and insulating layer 104 grow the nanotube 132 which may subsequently falls onto the SiO₂ insulating layer 104, after being aligned during growth.

For example, the electrodes 112 and 114 may be patterned (e.g., using photolithography and liftoff) having a length, width and height of about 0.8 cm, 0.3 cm and 50-100 nm, respectively, with a space between the electrodes of about 10 microns. The catalyst/dopant/metal oxide material portions 122 and 124 are patterned as strips at about 5 microns high and 0.4 cm in length. A voltage of between about 3V and 20V is applied to the electrodes 112 and 114, with a resistor (e.g., 40kΩ) being used to limit current. The nanotube 132 is then grown in the CVD chamber at 600-1200° C. using about 720 mL/min of methane gas flow, 500 mL/min of hydrogen gas flow and 12 mL/min of ethylene gas flow, for about 2 minutes. Pure hydrogen gas may also be flowed into the CVD chamber during heating and cooling steps and used to inhibit oxidation of the electrodes 112 and 114.

In one embodiment, the catalyst/dopant/metal oxide solution portions 122 and 124 are patterned using a double-layer photolithography approach, wherein an upper layer (e.g., conventional photoresist) is patterned using a conventional photolithography approach and wells are formed in via plasma etching. The upper layer is then removed via exposure to a high flux of light and subsequent development. Catalyst/dopant/metal oxide solution is then deposited from a methanol suspension into the patterned lower layer, which is followed by liftoff of the lower layer.

Y-SWNTs formed under the above-described process conditions were aligned in the direction of the electric field that was applied during the growth process. Finally, using nano-patterning techniques, catalyst/dopant solution nanoparticles were positioned at desired positions, thus influencing locations where nucleation takes place. Thus, the procedures provide methods for synthesizing Y-SWNTs having controlled density, position, and growth direction.

1. A method of forming Y-branched single-wall nanotubes comprising the steps of:
applying, to a substrate, a plurality of particles of a solution of a mixture of metal catalyst ions, dopant metal ions, and metal oxide particles, wherein the dopant metal forms a dopant metal carbide more easily than formation of a catalyst metal carbide at a reaction temperature;
drying the solution of catalyst metal ions, dopant metal ions and metal oxide particles on said substrate to form defined nanotube nucleation sites;
placing the substrate, containing said dried catalyst metal, dopant metal and metal oxide mixture in a CVD reactor;
heating the CVD reactor to the reaction temperature in the range of about 600° C. to about 1200° C.; and
flowing a hydrocarbon gas through said CVD reactor at a flow rate sufficient to form said Y-branched single-wall nanotubes.

2. The method of claim 1, wherein the catalyst metal ions are iron ions.

3. The method of claim 2, wherein the dopant metal ions are selected from the group consisting of Ti, Zr, Hf, V, Nb, Tu, Cr, Mo, W ions, and mixtures thereof.

4. The method of claim 3, wherein the dopant metal ions are selected from Ti, Zr and Mo ions.

5. The method of claim 4, wherein the dopant metal ions are Mo ions.

6. The method of claim 1, wherein the solution particles are applied to a surface of the substrate in defined areas and a solution particles applied to one area differ from a solution particle applied to another area by containing different catalyst metal and/or dopant metal ions.

7. The method of claim 1, wherein the Y-branched single-wall nanotubes formed contain conducting nanotube stems and semiconducting Y-branches.

8. A single-wall Y-branched carbon nanotube having a stem formed in an arm-chair hexagonal carbon structure and having Y-branches formed from a zig-zag hexagonal carbon structure.

9. A Y-junction single-wall carbon nanotube device comprising:
a Y-branched single-wall carbon nanotube, formed by the process of claim 1, including a stem, a first arm, and a second arm, wherein a first proximal end of the stem, first arm, and second arm are coupled at a heterojunction;
a first electrode electrically coupled to a distal end of the stem;
a second electrode electrically coupled to a distal end of the first arm;
a third electrode electrically coupled to a distal end of the second arm.

10. The device of claim 9, wherein the length of the stem is longer than the length of the first and second arms.

11. The device of claim 9, wherein the metal electrodes comprise at least one of gold, titanium, platinum and nickel.

12. The device of claim 9, wherein the first electrode, second electrode, and third electrode form a source, drain, and gate terminal, respectively, of an ambipolar device.

13. The device of claim 9, wherein a positive voltage applied to the second arm enables current flow in a first direction between the stem and first arm.

14. The device of claim 13, wherein a negative voltage applied to the second arm enables current flow in a second direction between the stem and first arm.

15. The device of claim 9, wherein the stem comprises a metallic material and the first and second arms comprise a semiconducting material.

16. The device of claim 15, wherein the stem comprises a p-doped semiconducting material and the first and second arms comprise a semiconducting material.

17. The device of claim 15, wherein the stem comprises a semiconducting material and the first arm comprises a p-doped semiconducting material.
